(19) United States
(12) Patent Application Publication
(10) Pub. No.: US 2015/0123219 A1
(43) Pub. Date: May 7, 2015

(54) ELECTRODE SYSTEM FOR A MICROMECHANICAL COMPONENT

(71) Applicant: Robert Bosch GmbH, Stuttgart (DE)

(72) Inventor: Johannes CLASSEN, Reutlingen (DE)

(21) Appl. No.: 14/533,777

(22) Filed: Nov. 5, 2014

(30) Foreign Application Priority Data
Nov. 7, 2013 (DE) 10 2013 222 676.4

(51) Int. Cl. B81B 3/00; B81C 1/00

(52) U.S. Cl. CPC B81B 3/0086; B81C 1/00349; B81B 2203/04
USPC 257/415; 438/50

(57) ABSTRACT

An electrode system for a micromechanical component, including: at least one first functional layer including electrodes formed therein, at least one second functional layer, and at least one third functional layer, the third functional layer being usable as an electrical printed conductor, the third functional layer being at least sectionally completely free of oxide material.

### RELATED APPLICATION INFORMATION

The present application claims priority to and the benefit of German patent application no. 10 2013 221 055.8, which was filed in Germany on Oct. 17, 2013, the disclosure of which is incorporated herein by reference.

### FIELD OF THE INVENTION

The present invention relates to an electrode system for a micromechanical component. Furthermore, the present invention relates to a method for manufacturing an electrode system for a micromechanical component.

### BACKGROUND INFORMATION

Micromechanical inertial sensors for measuring acceleration and rotation rate are known in the automotive and consumer fields for various applications. Such sensors include, inter alia, a surface-micromechanical layer, the thickness of which is typically between approximately 10 μm and approximately 30 μm. A thin printed conductor level situated underneath, the thickness of which is normally between approximately 200 nm and approximately 1000 nm, is used for flexible wiring and contacting of movable structures.

The two functional layers are separated from one another via an oxide material, contact holes resulting by way of the opening of the oxide material, which ensure a mechanical and electrical connection of one of the functional layers to the other functional layer.

German patent document DE 10 2012 200 740 A1 discusses a micromechanical component and a method for manufacturing a micromechanical component. A safeguard against undercutting of narrow printed conductors of a functional layer under a closed layer of a further functional layer is described.

German patent document DE 10 2009 045 391 A1 discusses a micromechanical structure and a method for manufacturing a micromechanical structure. A micromechanical functional layer is described, to implement an electrode carrier, on which individual, stationary electrodes of a further functional layer are situated, the electrode carrier partially extending below a further electrode comb of the further functional layer and bypassing it. In this way, good decoupling of packaging stress and resulting substrate deformation are to be achieved.

### SUMMARY OF THE INVENTION

It is one object of the present invention to provide an improved electrode system for a micromechanical component.

The object may be achieved according to a first aspect by an electrode system for a micromechanical component, including:
at least one first functional layer including electrodes formed therein;
at least one second functional layer; and
at least one third functional layer, the third functional layer being usable as an electrical printed conductor, characterized in that the third functional layer is at least sectionally completely free of oxide material.

According to the present invention, an additional wiring level in the form of a third functional layer is provided. Due to the fact that the third functional layer is configured to be relatively thick, it may advantageously be completely free of oxide material at least sectionally. In this way, it is possible to minimize parasitic capacitances of the third functional layer configured as a printed conductor level. In addition, as a result of the thicker configuration of the printed conductor level of the third functional layer and the high mechanical stability linked thereto, a compact design with respect to the surface area of the overall wiring of the electrode system results, since the printed conductors may be configured to be comparatively narrow.

According to another aspect, the object is achieved by a method for manufacturing an electrode system for a micromechanical component, including the following steps:
providing a first functional layer;
forming electrodes within the first functional layer;
providing a second functional layer; and
providing a third functional layer, a thickness of the third functional layer being configured in such a way that the third functional layer is usable as an electrical printed conductor; and
at least partially completely freeing the third functional layer of oxide material.

Specific embodiments of the electrode system according to the present invention and the method according to the present invention are the subject matter of subclaims.

According to one specific embodiment of the electrode system according to the present invention, it is provided that a thickness of the third functional layer is at least approximately four times greater than a thickness of the second functional layer. Due to this specific embodiment of the third functional layer, it is sufficiently stable as an electrical printed conductor, may be completely undercut, and has favorable mechanical properties.

Another specific embodiment of the electrode system according to the present invention provides that the third functional layer is essentially situated between the first and the second functional layers. A high degree of design freedom or flexibility of printed conductor structures for the micromechanical component is thus facilitated.

According to another specific embodiment of the electrode system according to the present invention, it is provided that at least one printed conductor of the second functional layer and at least one printed conductor of the third functional layer are situated crosswise, the crossing being situated below the first functional layer. Advantageous bypasses of the second functional layer via the third functional layer are thus made possible, which are situated below movable structures of the first functional layer and in this way enable a compact configuration of the component.

Another specific embodiment of the electrode system according to the present invention provides that a width of the third functional layer is implemented differently at least sectionally. In this way, it may advantageously be determined whether or not oxide material should remain during the course of an etching process. Furthermore, structures of the third functional layer may thus be situated offset to one another, whereby as a result wiring surface area may be saved. This is advantageous for rotation rate sensors, for example, which conduct multiple different potentials on electrodes, because wiring problems are thus solvable in a flexible way. As a result, this means more wiring options and thus a gain in design freedom. In addition, due to the small surface area of the printed conductor level of the third functional layer, small undesirable parasitic capacitances advantageously result. A signal quality of a signal generated using the micromechanical component may advantageously be high in this way.

One advantageous refinement of the electrode system according to the present invention provides that oxide material which is situated between the functional layers may be structured with the aid of an etching process. In particular, gas phase etching may be used for this purpose, which acts uniformly on all oxide layers.

According to another specific embodiment of the electrode system according to the present invention, it is provided that the third functional layer has holes for an access of an etching medium. In this way, being able to remove all oxide material situated between or below the functional layers completely and in a short time is advantageously facilitated.

Another specific embodiment of the electrode system according to the present invention is characterized in that oxide material is only structured at those points at which a conductive contact to one of the functional layers is formed. In this way, a favorable type of a possible contact between functional layers is provided.

Another specific embodiment of the electrode system according to the present invention provides that the second functional layer and the third functional layer are mechanically and/or electrically connectable to one another. In this way, a multifaceted use of the functional layers within the micromechanical component is facilitated.

The present invention is described in greater detail hereafter by further features and advantages on the basis of multiple figures. All features which are described or illustrated form the subject matter of the present invention alone or in any arbitrary combination, regardless of their recapitulation in the patent claims or their back-reference, and also regardless of their wording in the description or their representation in the figures. Identical or functionally identical elements have identical reference numerals.

### BRIEF DESCRIPTION OF THE DRAWINGS

FIG. 1 shows a top view of a conventional electrode system of an inertial sensor.

FIG. 2 shows a top view of the conventional electrode system from FIG. 1 having a different degree of detail.

FIG. 3 shows a view through section line A-B from FIG. 2.

FIG. 4 shows a view through section line C-D from FIG. 2.

FIG. 5 shows a top view of one specific embodiment of the electrode system according to the present invention.

FIG. 6 shows a top view of the electrode system from FIG. 5 having a different degree of detail.

FIG. 7 shows a top view of the electrode system from FIG. 5 having a different degree of detail.

FIG. 8 shows a view through section line A-B from FIG. 7.

FIG. 9 shows a view through section line A′-B′ from FIG. 7.

FIG. 10 shows a view through section line C-D from FIG. 7.

FIG. 11 shows a schematic flow chart of one specific embodiment of the method according to the present invention.

### DETAILED DESCRIPTION

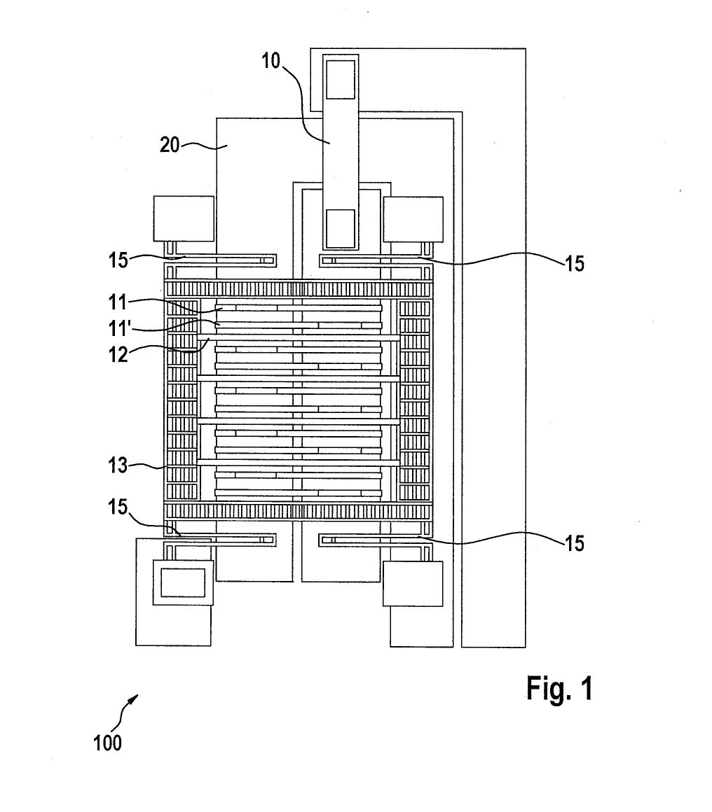

FIG. 1 shows a schematic diagram in a top view of a micromechanical lateral acceleration sensor 100, which may measure a physical acceleration parallel to the substrate level. A seismic mass, which is situated as a frame structure 13, having movable electrodes 12 is deflected in the event of acceleration, geometric deflections being measured via a change of a gap of movable electrodes 12 in relation to first stationary electrodes 11 and second stationary electrodes 11′. Stationary electrodes 11, 11′ are connected via contact holes to a second micromechanical functional layer 20.

A MEMS structure of a first micromechanical functional layer 10 is free of a sacrificial oxide or oxide material 40 via a removal (not shown in FIG. 1) between first functional layer 10 and second functional layer 20. Oxide material 40 is generally etched using gaseous HF. This process is time-controlled, which means that the longer it lasts, the more extensive is the undercutting of the silicon structures of functional layers 10, 20, which are not themselves attacked by the HF. In addition to the desired removal of oxide material 40 under the movable structures, in this way undesirable etching of oxide material 40 is also carried out at points where silicon structures are to remain fixedly connected to a substrate 1, in particular at the edges of second functional layer 20.

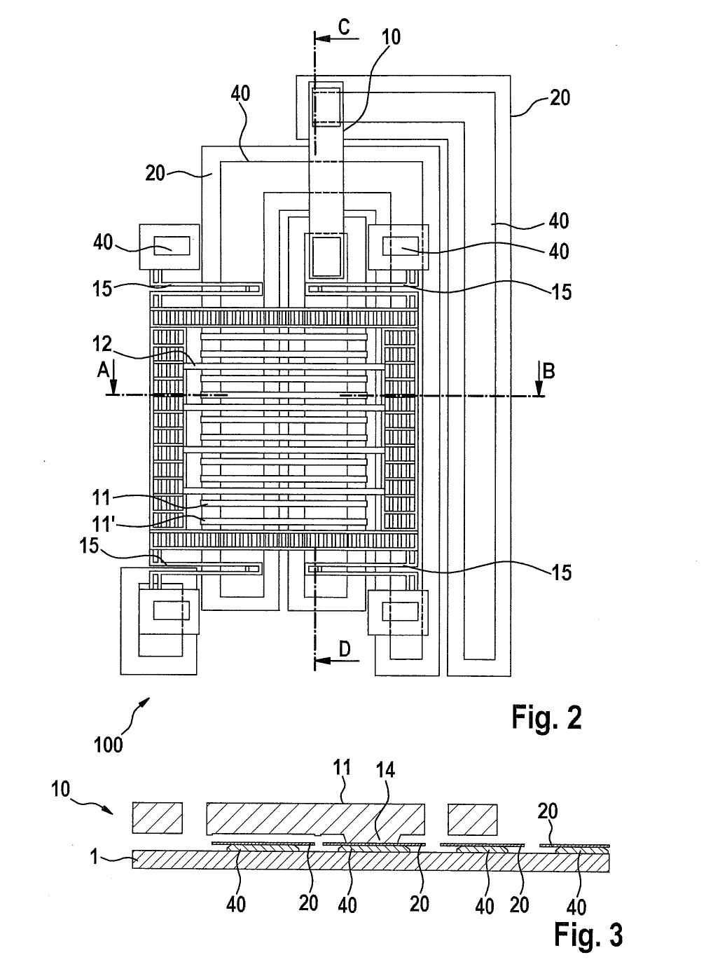

FIG. 2 shows the same top view of the electrode system of acceleration sensor 100 from FIG. 1 having a different degree of detail. In the figure, oxide material 40 remaining below second functional layer 20 after the mentioned gas phase etching, and also oxide material 40 between first functional layer 10 and third functional layer 30 below the mechanical suspensions of the movable structure of first function layer 10, are also apparent.

One disadvantage of this conventional system is therefore a higher space requirement for second functional layer 20, which functions as a printed conductor. To reliably prevent it from being completely undercut, second functional layer 20 must typically be configured to be at least approximately 30 μm to approximately 40 μm wide. Completely undercut printed conductors may bulge up noticeably already over short lengths under certain circumstances and have a tendency toward buckling; in addition, they are very fracture-sensitive when moving physical masses strike thereon upon incidence with a high mechanical load.

Due to their large width, the printed conductors of second functional layer 20 have high parasitic capacitances in relation to substrate 1, which very negatively influence a signal-to-noise ratio, a linearity, a settling time, or a power consumption of the micromechanical sensor, inter alia, and may therefore corrupt a signal of the sensor. A further disadvantage of the described conventional technology is a high space requirement for electrical bridges or crossings of printed conductors. Specifically, since conventionally only two conductive layers in the form of first functional layer 10 and second functional layer 20 are available, bridges must always be formed in first functional layer 10 and must therefore be situated laterally and therefore in a space-consuming way adjacent to the movable structures.

FIGS. 1 and 2 show in the top area a corresponding bridge of first functional layer 10, which crosses over a printed conductor lying underneath second functional layer 20.

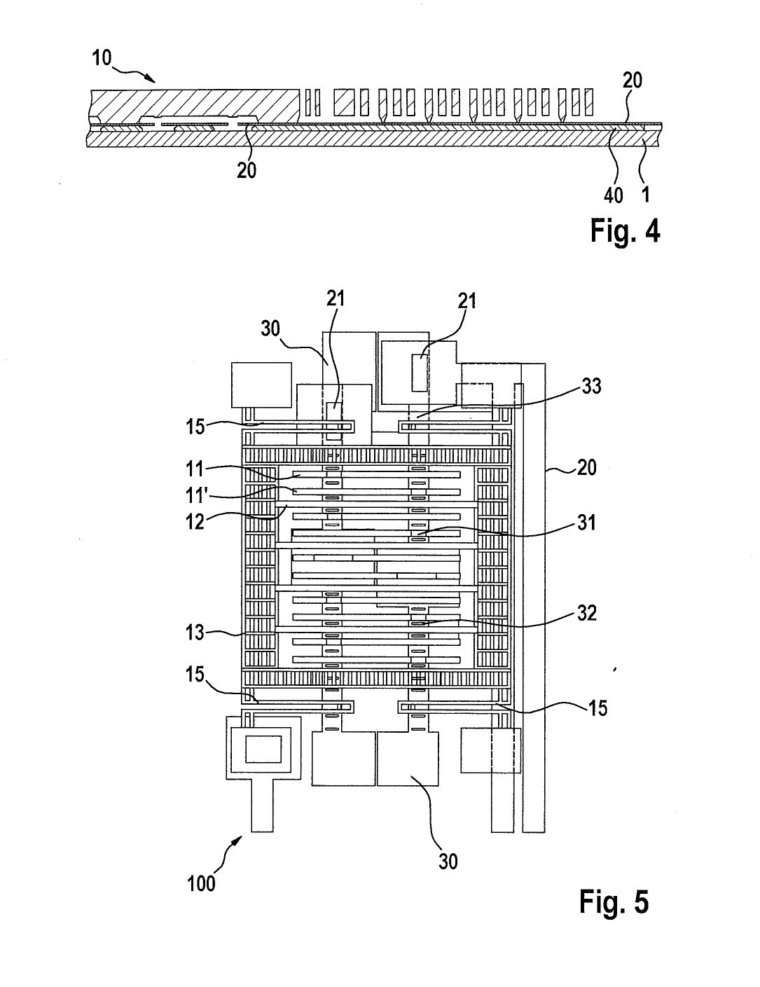

FIGS. 3 and 4 show, for better understanding of the conventional technology, top views or cross sections along section lines A-B (FIG. 3) and C-D (FIG. 4) from FIG. 2.

FIG. 3 shows the conventional structure, which is situated on a substrate 1, having oxide material 40, second functional layer 20, and micromechanical movable structure in first functional layer 10. A contact hole 14 is provided for suspending electrode 11 of first functional layer 10 on second functional layer 20. It is apparent that second functional layer 20, which functions as a printed conductor, is partially strongly undercut in edge areas, which has the result that the printed conductors are partially freestanding or overhanging at their edges. This may disadvantageously mean mechanical instability of the printed conductor.

FIG. 4 shows that below a right area of first functional layer 10, which is configured as a spring, frame, or electrode area, the printed conductor of second functional layer 20 is essentially completely underlaid with oxide material 40. This disadvantageously results in high parasitic capacitance values and may result in the above-mentioned disadvantageous effects for signal quality.

For reducing parasitic effects, implementing printed conductors coming from a chip periphery partially in first functional layer 10 instead of in second functional layer 20 is known in the related art. This does result in reduced parasitic effects, but disadvantageously means an increased surface area requirement, since then not only the bridges, but rather also the supply printed conductors must lie adjacent to the movable structures of first functional layer 10.

In addition, this method is not suitable for contacting individual stationary electrodes, which lie within a closed frame mass of a sensor, as shown in FIG. 1 and FIG. 2, for example. For this purpose, an additional wiring level below or optionally above the level of first functional layer 10 is always required. Correspondingly, an additional wiring level of second functional layer 20 is always also used in the area of the movable sensor core in the related art.

According to the present invention, it is provided that with the aid of a third micromechanical functional layer 30, a reduction of parasitic capacitances and a compact arrangement or configuration for the wiring of surface-micromechanical components is provided. The micromechanical components may be configured as micromechanical sensors, for example, as inertial sensors in the form of rotation rate sensors or acceleration sensors.

FIG. 5 shows a schematic top view of one specific embodiment of the electrode system according to the present invention. The movable sensor structure including suspension and stationary electrodes in first functional layer 10 are identical to the system shown in FIGS. 1 and 2. The differences are in the concept of the electrical wiring.

According to the present invention, a further functional layer 30 (apparent in outlines in FIG. 5) is provided, which is configured to be thicker than second functional layer 20. With the aid of third functional layer 30, in particular a wiring functionality is provided, an overall wiring which may be implemented via the two functional layers 20, 30. All functional layers 10, 20, 30 may be formed from polycrystalline silicon, different deposition methods being used to form different thicknesses of functional layers 10, 20, 30.

Contact holes 21 between second functional layer 20 and third functional layer 30, and also contact holes 31 between first functional layer 10 and third functional layer 30, are apparent. The supply of the printed conductors for electrodes 11, 11′ is also carried out here on the right side from below via the webs of second functional layer 20, which are apparently configured to be significantly narrower in this case, however, than those of the systems shown in FIGS. 1 and 2. The lesser width is possible in that they are substantially shielded against the undercutting during the gas phase etching by the level of third functional layer 30 lying above. Etching holes 32 may be configured as narrow slots in third functional layer 30, to accomplish targeted undercutting of printed conductors of third functional layer 30.

Due to the significantly increased layer thickness of third functional layer 30, which is configured to be approximately four times as thick as second functional layer 20, in comparison to second functional layer 20, the printed conductors of third functional layer 30 may also be completely undercut over significantly greater lengths. As a result, this means that the printed conductors of third functional layer 30 essentially may not bulge up and are therefore mechanically stable. Therefore, they may also be provided to be significantly narrower than conventional printed conductors of second functional layer 20 and are afflicted with substantially lower parasitic capacitances than conventional printed conductors of second functional layer 20 due to the fact that no oxide material 40 is situated below them at least sectionally. In spite of the lesser width, the electrical resistance of the overall wiring therefore does not significantly increase, since due to the greater thickness of the printed conductors of third functional layer 30, the cross-sectional area and therefore the electrical resistance may be kept essentially at an unchanged level.

In the upper area of FIG. 5, the contacting of the printed conductors of second functional layer 20 is carried out on the level of third functional layer 30; in this area, crossing over of the printed conductor of second functional layer 20 with a printed conductor of third functional layer 30 is also implemented. This area may therefore advantageously already be used again for a useful structure of first functional layer 10, in contrast to the conventional bridge structure of the system from FIGS. 1 and 2.

A bending spring 15 of first functional layer 10 thus lies partially above the bridge made up of second functional layer 20 and third functional layer 30. The stationary electrodes in the sensor core area are borne in the system of FIG. 5 by printed conductors of third functional layer 30. For the mentioned reasons, these printed conductors may be configured to be significantly narrower, for example, approximately 5 μm to approximately 20 μm. In addition, for the purpose of a reduction of the parasitic capacitance, they may also be undercut in a targeted way via narrow etching holes or additional slots 32 in third functional layer 30.

The completely undercut printed conductor area may not be of any arbitrary size, however, but rather is essentially dependent on the thickness of third functional layer 30 and the mass of the structures fastened thereon of first functional layer 10. At relatively low layer thicknesses of third functional layer 30 in the range of approximately 2 μm, completely undercut areas having lengths of 100 μm and more may already be implemented.

In the case of greater printed conductor lengths, for reasons of stability, intermediate supports made of oxide material 40 are to be situated for the printed conductors of third functional layer 30. Therefore, in the system of FIG. 5, the printed conductor width of third functional layer 30 is enlarged in the area of the particular middle stationary electrode, to prevent complete undercutting locally in this way and to ensure a mechanical attachment of third functional layer 30 to substrate 1 with the aid of oxide material 40. Using this optional local attachment, the stiffness of the printed conductor structure may advantageously be massively increased. Of course, in the case of a larger sensor structure, multiple attachment points may also be situated, for example, regularly spaced apart. In the case of small sensor structures and/or thick designs of third functional layer 30, in contrast, such an attachment is not even necessary under certain circumstances.

Due to the fact that third functional layer 30 is sectionally completely undercut, a small width and therefore a small surface area of the printed conductors may be implemented, which in turn results in an advantageously low parasitic capacitance according to the capacitor formula. In this way, the quality or the signal-to-noise ratio of an electrical signal tapped from the electrodes of the sensor structure may advantageously be significantly improved.

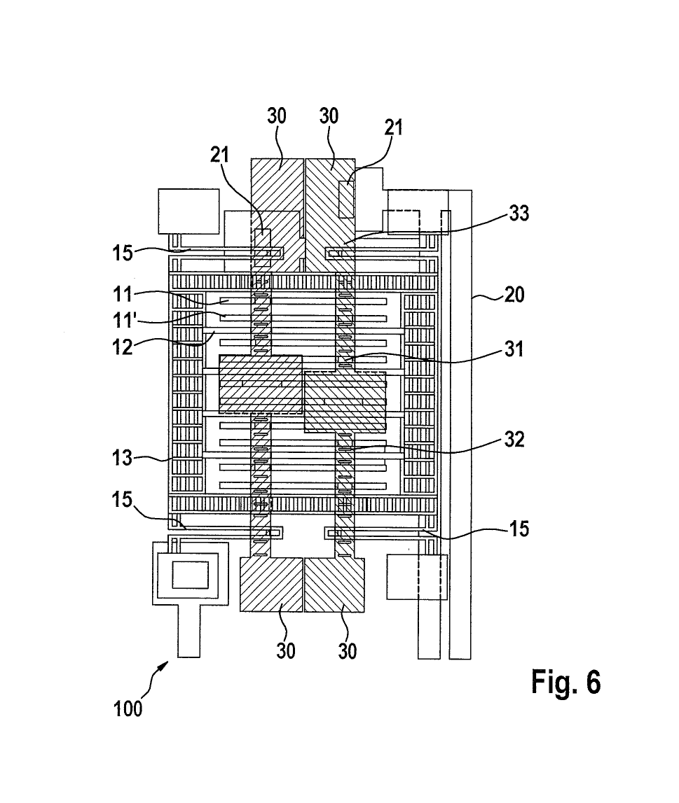

Since the actual printed conductors of third functional layer 30 in FIG. 5 are difficult to recognize in outlines due to the narrow gap to the adjacent structures of third functional layer 30, the top view of FIG. 6 shows the two printed conductors of third functional layer 30, which bear the stationary electrodes of first functional layer 10, better visible in shaded emphasis.

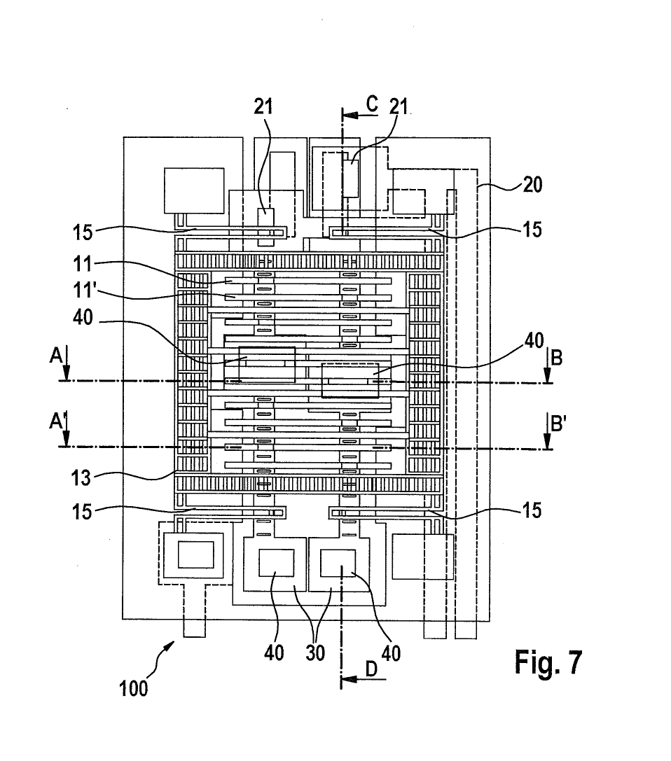

The top view of the electrode system according to the present invention from FIG. 7 shows, in addition to FIG. 5, oxide material 40 below the level of third functional layer 30 and above the level of second functional layer 20, which is used to form anchoring points for the mechanical fixing of the printed conductors of third functional layer 30. Completely undercut areas between the printed conductors of third functional layer 30 in the sensor core area and also a non-undercut area in the middle of the sensor structure and above and below bending springs 15 are apparent, inter alia.

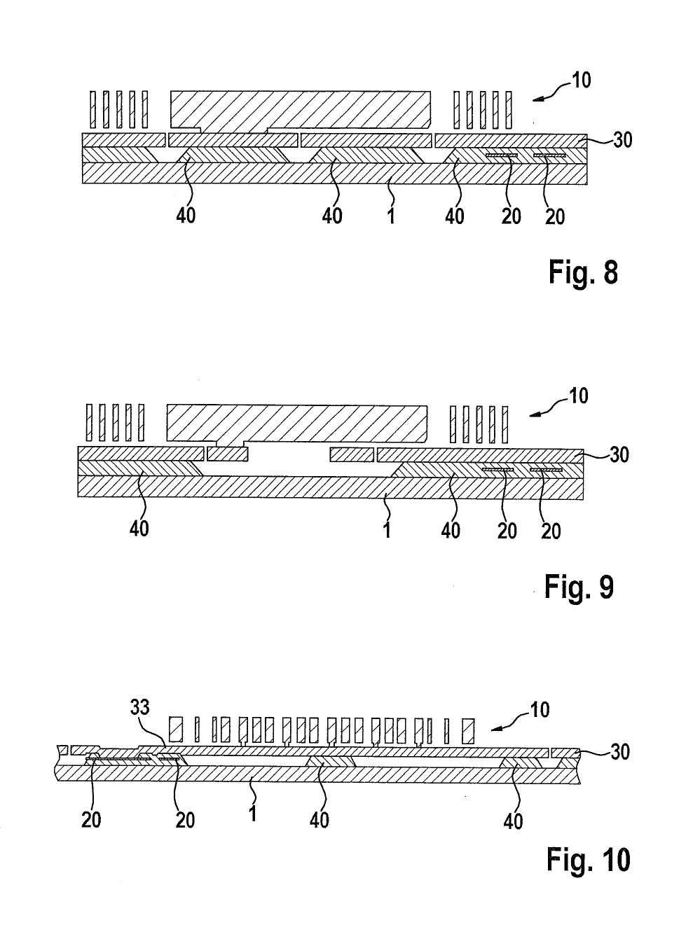

FIGS. 8 through 10 show top views or cross sections of FIG. 7, which are based on process simulations, and are used for better understanding of the top view illustrations of FIG. 5 through FIG. 7. In each case, the etchings of oxide material 40 situated in three layers and the contact holes between adjacent silicon levels of functional layers 10, 20, 30 are well recognizable.

FIG. 8 shows a top view along section line A-B from FIG. 7. The wide printed conductor sections, which are implemented with the aid of third functional layer 30, in the area of the intermediate supports, which are only partially undercut, are well recognizable

FIG. 9 shows a cross section along section line A′-B′ from FIG. 7. In this section, the printed conductors implemented with the aid of third functional layer 30 are configured to be narrow and are therefore completely undercut.

FIG. 10 shows a cross-sectional view along a section line C-D from FIG. 7. It is apparent that an area of the printed conductor of third functional layer 30 below the central electrode structure is substantially free of oxide material 40, which causes a small parasitic capacitance of the printed conductor. An electrical contact of third functional layer 30 to second functional layer 20, which is shown in the left area of the figure, and an insulated crossing 33 of third functional layer 30 over second functional layer 20 are also apparent. Due to the manifold contact or crossing possibilities of second functional layer 20 with third functional layer 30, a high degree of design freedom of a printed conductor guidance is advantageously facilitated, in particular below the movable MEMS structures of first functional layer 10.

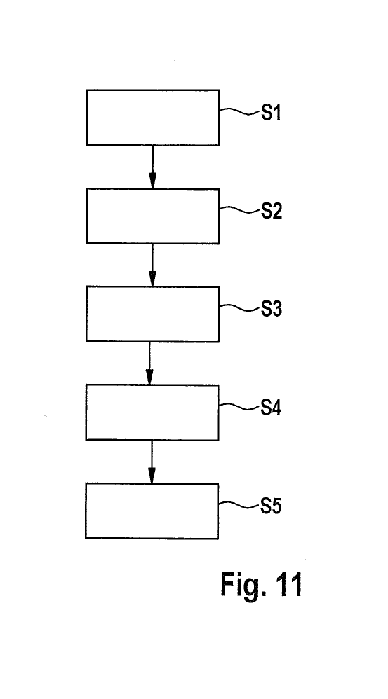

FIG. 11 shows a schematic sequence of one specific embodiment of the method according to the present invention.

In a first step S1, a first functional layer 10 is provided.

In a second step S2, electrodes are formed within first functional layer 10.

In a third step S3, a second functional layer 20 is provided.

In a fourth step S4, a third functional layer 30 is provided, a thickness of third functional layer 30 being configured in such a way that third functional layer 30 is usable as an electrical printed conductor.

Finally, in a fifth step S5, third functional layer 30 is at least partially completely free of oxide material 40.

Although the above-described exemplary embodiment of the electrode system according to the present invention was represented for an acceleration sensor 100 for reasons of simplicity, the present invention may also be used, of course, for any micromechanical component which detects a measuring signal with the aid of movable micromechanical MEMS structures (for example, resonator, rotation rate sensor, pressure sensor, etc).

In summary, a device and a method for an electrode system of a micromechanical component are provided by the present invention. It is provided according to the present invention that a third functional layer is used for wiring purposes, which may be at least sectionally completely undercut due to its thickness and therefore may be free of oxide material.

In this way, electrical wiring within the component structure may be implemented in a robust, multifaceted, flexible, and space-saving way. In addition, the printed conductors implemented in the third functional layer may be configured to be narrow and robust due to the thickness of the third functional layer, whereby complete undercutting is possible, which advantageously facilitates a low-parasitic embodiment of the wiring. As a result, a compact, low-parasitic electrode system for micromechanical components may be implemented.

A high degree of design freedom is advantageously enabled by the electrode system according to the present invention, multiple printed conductor levels having different electrical potentials being able to be guided or situated variably within the sensor structure. This is achieved in that the printed conductors of the second and third functional layer are situated spatially offset in relation to one another, whereby space resources of the sensor structure are utilized in the best possible way. In a modification of the electrode system according to the present invention, it is advantageously also possible to provide the layer system shown made up of first, second, and third functional layers 10, 20, 30 within a micromechanical component (not shown), virtually stacked multiple times.

Those skilled in the art may change the described features or combine them with one another in a suitably appropriate manner, without deviating from the present invention.

What is claimed is:

1. An electrode system for a micromechanical component, comprising:
at least one first functional layer including electrodes formed therein;
at least one second functional layer; and
at least one third functional layer, which is usable as an electrical printed conductor;
wherein the third functional layer is at least sectionally completely free of oxide material.

2. The electrode system of claim 1, wherein a thickness of the third functional layer is at least approximately four times as great as a thickness of the second functional layer.

3. The electrode system of claim 1, wherein the third functional layer is essentially situated between the first and the second functional layers.

4. The electrode system of claim 3, wherein at least one printed conductor of the second functional layer and at least one printed conductor of the third functional layer are situated crosswise, the crossing being situated below the first functional layer.

5. The electrode system of claim 1, wherein a width of the third functional layer is configured to be different, at least sectionally.

6. The electrode system of claim 1, wherein oxide material situated between the functional layers is structured with the aid of an etching process.

7. The electrode system of claim 6, wherein the third functional layer has holes for an access of an etching medium.

8. The electrode system of claim 6, wherein oxide material is only structured at those points at which a conductive contact to one of the functional layers is formed.

9. The electrode system of claim 1, wherein the second functional layer and the third functional layer are at least one of mechanically and electrically connectable to one another.

10. A micromechanical component, comprising:
an electrode system for a micromechanical component, including:
at least one first functional layer including electrodes formed therein;
at least one second functional layer; and
at least one third functional layer, which is usable as an electrical printed conductor;
wherein the third functional layer is at least sectionally completely free of oxide material.

11. A method for manufacturing an electrode system for a micromechanical component, the method comprising:
providing a first functional layer;
forming electrodes within the first functional layer;
providing a second functional layer; and
providing a third functional layer, a thickness of the third functional layer is configured so that the third functional layer is usable as an electrical printed conductor; and
at least partially completely freeing the third functional layer of oxide material.

12. The method of claim 11, wherein a thickness of the third functional layer is at least approximately four times as great as a thickness of the second functional layer.

13. The method of claim 11, wherein the third functional layer is essentially situated between the first and the second functional layers.

14. The method of claim 13, wherein at least one printed conductor of the second functional layer and at least one printed conductor of the third functional layer are situated crosswise, the crossing being situated below the first functional layer.

15. The method of claim 11, wherein a width of the third functional layer is configured to be different, at least sectionally.

16. The method of claim 11, wherein oxide material situated between the functional layers is structured with the aid of an etching process.

17. The method of claim 16, wherein the third functional layer has holes for an access of an etching medium.

18. The method of claim 16, wherein oxide material is only structured at those points at which a conductive contact to one of the functional layers is formed.

19. The method of claim 11, wherein the second functional layer and the third functional layer are at least one of mechanically and electrically connectable to one another.
